(19) United States
(12) Patent Application Publication
(10) Pub. No.: US 2025/0132131 A1
(43) Pub. Date: Apr. 24, 2025

(54) PLASMA MODULATION APPARATUS FOR SUBSTRATE PROCESSING SYSTEM

(71) Applicant: ASM IP Holding B.V., Almere (NL)

(72) Inventors: Akshay Gunaji, Hwaseong-si (KR); Sergei Golovkov, Tokyo (JP); ByungWook Son, Hwaseong-si (KR); Gopu Krishna, Hwaseong-si (KR); DaeYoun Kim, Seo-gu (KR)

(21) Appl. No.: 18/919,874

(22) Filed: Oct. 18, 2024

Related U.S. Application Data
(60) Provisional application No. 63/545,243, filed on Oct. 23, 2023.

(51) Int. Cl. H01J 37/32

(52) U.S. Cl. CPC H01J 37/32183; H01J 37/32137; H01J 37/32174; H01J 37/32935; H01J 2237/3323

(57) ABSTRACT

A plasma modulation apparatus for use in a substrate processing system is disclosed. The apparatus comprising: a plurality of radio frequency (RF) paths connected to N different meshes, wherein a susceptor of the substrate processing system is divided into the N different meshes and N is an integer equal to or greater than 2, wherein each of the RF paths comprises: an RF rod connected to a mesh and configured to transmit RF signal from the meshes; a Voltage-Current (VI) sensor connected to the RF rod and configured to measure a current from the RF rod; and a variable impedance circuit connected to the VI sensor and configured to change an impedance of the RF path and further configured to be grounded, wherein each of the RF paths are grounded separately and each of the RF paths corresponds to a different mesh, respectively.

### CROSS-REFERENCE TO RELATED APPLICATIONS

This application claims priority to U.S. Provisional Patent Application Ser. No. 63/545,243 filed Oct. 23, 2023 titled PLASMA MODULATION APPARATUS FOR SUBSTRATE PROCESSING SYSTEM, the disclosure of which is hereby incorporated by reference in its entirety.

### FIELD OF INVENTION

The present disclosure relates to a substrate processing system, more particularly to an apparatus for modulating plasma environment inside of a reaction chamber of a substrate processing system.

### BACKGROUND OF THE DISCLOSURE

On-wafer deposition and sputter uniformity are closely associated with the plasma profile, such as density in the reaction chamber. Any non-uniformity in the plasma profile directly impacts the on-wafer uniformity for deposition & sputter in a Plasma Enhanced Atomic Layer Deposition (PEALD) Process.

The present disclosure provides a plasma tuning hardware capable of resolving the on-wafer non-uniformity issues during a PEALD or Sputtering process.

The present disclosure provides an apparatus achieving on-wafer uniformity for deposition & sputter by modulating impedances of the radio frequency (RF) Return paths to the ground.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a plasma modulation apparatus for use in a substrate processing system, the apparatus comprising a plurality of radio frequency (RF) paths connected to N different meshes, wherein a susceptor of the substrate processing system is divided into the N different meshes and N is an integer equal to or greater than 2, wherein each of the RF paths comprises: an RF rod connected to a mesh and configured to transmit RF signal from the meshes; a Voltage-Current (VI) sensor connected to the RF rod and configured to measure a current from the RF rod; and a variable impedance circuit connected to the VI sensor and configured to change an impedance of the RF path and further configured to be grounded, and wherein each of the RF paths are grounded separately and each of the RF paths corresponds to a different mesh, respectively.

In accordance with another embodiment there may be provided, the apparatus further comprising: an RF filter configured to filter out noise from the RF rod.

In accordance with another embodiment there may be provided, the apparatus further comprising: a controller coupled to each of the RF paths and configured to monitor the currents of each of the VI sensors and to change impedances of each of the RF paths based on the monitored currents.

In at least one aspect, the controller is configured to change the impedances of each of the RF paths to be equal.

In accordance with another embodiment there may be provided, a substrate processing system comprising: a reaction chamber disposed with a showerhead and a susceptor for supporting a wafer, the susceptor divided into N different meshes, wherein N is an integer equal to or greater than 2; and a plasma modulation apparatus comprising: a plurality of radio frequency (RF) paths connected to the N different meshes, wherein each of the RF paths comprises: an RF rod connected to a mesh and configured to transmit RF signal from the meshes; a Voltage-Current (VI) sensor connected to the RF rod and configured to measure a current from the RF rod; and a variable impedance circuit connected to the VI sensor and configured to change an impedance of the RF path and further configured to be grounded, and wherein each of the RF paths are grounded separately and each of the RF paths corresponds to a different mesh, respectively.

In accordance with another embodiment there may be provided, the system further comprising: an RF filter configured to filter out noises from the RF rod.

In accordance with another embodiment there may be provided, the system further comprising: a controller connected to each of the RF paths and configured to monitor the currents of each of the VI sensors and to change impedances of each of the RF paths based on the monitored currents.

In at least one aspect, the system's controller is configured to change the impedances of each of the RF paths to be equal.

In accordance with another embodiment there may be provided, a method of modulating plasma in a substrate processing system, the system comprises a reaction chamber disposed with a susceptor, the susceptor being divided into N different meshes, wherein N is an integer equal to or greater than 2, and a plasma modulation apparatus comprising a plurality of radio frequency (RF) paths connected to the N different meshes, and each of the RF paths disposed an RF rod, a Voltage-Current (VI) sensor and a variable impedance circuit, the method comprising monitoring the currents of all the VI sensors from respective RF paths, deciding whether the monitored currents have the same value is true; and changing the impedances of variable impedance circuits from respective RF paths to be equal if decided to be false and repeat deciding if decided to be true.

In at least one aspect, the method further comprises filtering our noise from each of the RF rods.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a top-down overview of a susceptor (heater) with 3 meshes according to an embodiment of the present disclosure.

FIG. 2 illustrates a system overview of the substrate processing system according to an embodiment of the present disclosure.

FIG. 3 illustrates a detailed view of the plasma profile in the reaction chamber and 3 meshes of the susceptor according to an embodiment of the present disclosure.

FIG. 4 illustrates the detailed view of the plasma modulation apparatus according to an embodiment of the present disclosure.

FIG. 5 illustrates a method flowchart of plasma modulation according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

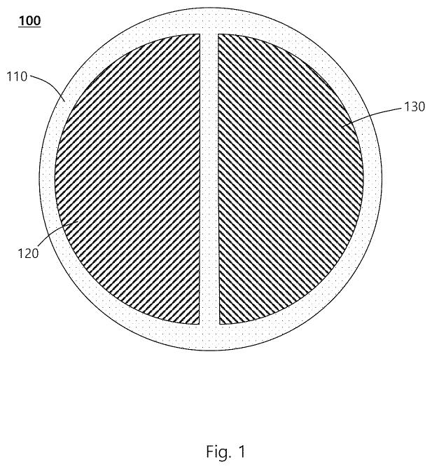

In FIG. 1, a susceptor 100 may be illustrated in detail. The susceptor 100 may be divided into 3 areas (meshes), such as a background mesh (mesh #1) 110, a left mesh (mesh #2) 120 and a right mesh (mesh #3) 130. Alternatively, a heater may be the target for mesh division in response to system requirements.

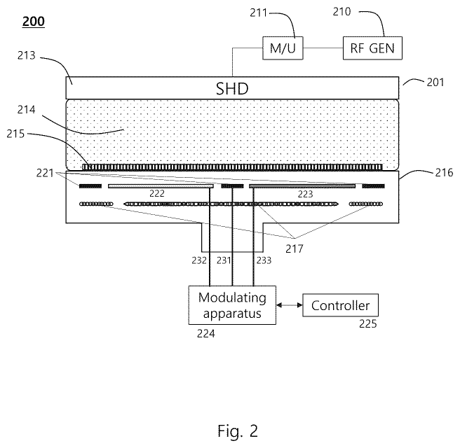

FIG. 2 illustrates an overview of the present disclosure.

A substrate processing system 200 may comprise a reaction chamber 201 with a showerhead 213, a susceptor 216, heater coils 217, RF generator 210 and matcher unit 211, and a plasma modulation apparatus 224 and a controller 225. Between the showerhead 213 and the susceptor 216, the space 214 may be formed for the generated plasma and a wafer 215 may be placed on the susceptor 216 so that the wafer 215 can be processed with the plasma and the reactant gas (not drawn).

The top of the susceptor 216 may be divided into several different meshes and 3 meshes may be used in the explanation in the present disclosure for simplicity.

The susceptor 216 may be divided into 3 meshes 221, 222, 223 like the susceptor 100 in FIG. 1. Each of the meshes 221, 22, 223 is connected to a plasma modulation apparatus 224 by 3 RF rods 231, 232, 233.

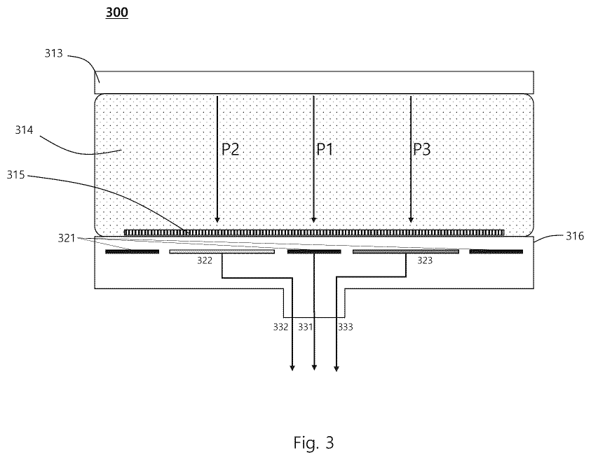

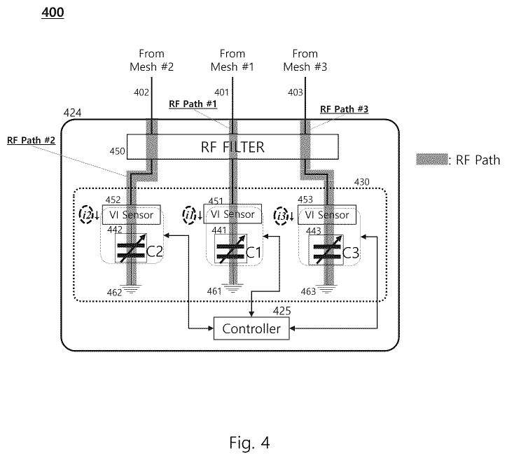

FIGS. 3 and 4 explain different aspects of the system and the apparatus in more detail.

FIG. 3 illustrates a detailed view of the reaction chamber 300 and a space 314 that contains a plasma profile in it, and 3 meshes 321, 322, 323 of the susceptor 316. In this reaction chamber 300 of a substrate processing system, a plasma in the space 314 may be generated between an upper electrode (showerhead) 313 and a lower electrode (susceptor) 316. A wafer 315 may be placed on the susceptor 316.

For adjusting a plasma profile of the space 314, the susceptor 316 may be divided into several areas. As shown in FIG. 3, the number of divided areas of the susceptor 316 would be 3. However, there could be more than 3 areas based on the need. The susceptor 316 may comprise different meshes 321, 322, 323. The 3 meshes 321, 322, 323 may be placed just beneath the surface of the susceptor 316. Alternatively, the meshes can be placed on the surface of the susceptor 316 based on the system requirements.

A left mesh (mesh #2) 322 may be mostly affected by a plasma profile right on top of it, i.e., (P2), while a right mesh (mesh #3) 323 affected by a plasma profile (P3). Also, a background mesh (mesh #1) 321 may be affected by a plasma profile (P1). Each mesh 321, 322, 323 may be connected to an RF rod 331, 332, 333, respectively.

FIG. 4 illustrates a plasma moderation apparatus according to an embodiment of present disclosure.

A plurality of RF rods 401, 402, 403 are attached to the meshes #1, #2, #3, respectively. Each of the RF rods may be connected to a VI sensor (Voltage-Current sensor) 451, 452, 453 that can measure voltage and current of plasma transmitted from the meshes.

The VI sensor 451 may be connected to a variable impedance circuit 441, which can vary the impedance of an electrical path established from the RF rod 401 to a ground 461 and the variable impedance circuit 441 may comprise at least one of coils, capacitances, or variable capacitances for changing the impedance. The variable impedance circuit 441 would be grounded to a ground 461. In the VI sensor 451, a current may be measured (i1) and this current reflects the plasma profile (P1).

The VI sensor 452 may be connected to a variable impedance circuit 442, which can vary the impedance of an electrical path established from the RF rod 402 to a ground 462 and the variable impedance circuit 442 may comprise at least one of coils, capacitances, or variable capacitances for changing the impedance. The variable impedance circuit 442 would be grounded to a ground 462. In the VI sensor 452, a current may be measured (i2) and this current reflects the plasma profile (P2).

The VI sensor 453 may be connected to a variable impedance circuit 443, which can vary the impedance of an electrical path established from the RF rod 403 to a ground 463 and the variable impedance circuit 443 may comprise at least one of coils, capacitances, or variable capacitances for changing the impedance. The variable impedance circuit 443 would be grounded to a ground 463. In the VI sensor 453, a current may be measured (i3) and this current reflects the plasma profile (P3).

The plasma uniformity in the reaction chamber 300 may be expressed “P1=P2=P3” (condition 1).

To make the plasma profiles in a chamber uniform (i.e., P1 =P2 =P3), the currents measured in the VI sensors 451, 452, 453 should be the same. Therefore, the currents i1, i2, i3 can be adjusted to be the same among themselves by changing impedances of the variable impedance circuits 441, 442, 443.

This same currents of i1, i2, i3 may be expressed “i1=i2=i3” (condition 2) and if ‘condition 1’ (P1=P2=P3) is satisfied then ‘condition 2’ (i1=i2=i3) is satisfied.

From the meshes to the grounds there may be more than one paths (as shown in FIG. 4) and each path may be called an RF path. Therefore, the number of RF paths may be equal to the number of the meshes. There are 3 RF paths in FIG. 4 as an example. RF path #1 may comprise an RF rod 401, a VI sensor 451, and a variable impedance circuit 441. RF path #2 may comprise an RF rod 402, a VI sensor 452, and a variable impedance circuit 442. RF path #3 may comprise an RF rod 403, a VI sensor 453, and a variable impedance circuit 443. RF path #1 may end up to a ground 461. RF path #2 may end up to a ground 462. RF path #3 may end up to a ground 463.

The plasma modulation apparatus 400 may comprise N number of RF paths where N is the number of meshes and N is equal to or greater than 2. Also, the apparatus 400 may further comprise an RF filter 450 and a controller 425.

The impedance changing of the variable impedance circuits 441, 442, 443 can be done manually or automatically.

For automatic impedance changing, the currents of the VI sensors 451, 452, 453 should be monitored constantly. This may be accomplished by the controller 425 being connected to each of the RF path, specifically to VI sensor and to variable impedance circuit. The controller 425 may monitor the VI sensors 451, 452, 453. When the measured currents i1, i2, i3 become different among themselves, the controller 425 may adjust the impedances of the circuits 441, 442, 443. The controller 425 may adjust the circuits 441, 442, 443 to satisfy the ‘condition 2’ (i1=i2=i3).

An RF filter 450 may be disposed in the RF rods 401, 402, 403. The RF filter 450 may filter out noise from the signals in the RF rods 401, 402, 403 so that each of the signals going into the VI sensors 451, 452, 453 may be clear for a better current measurement in each of the VI sensors.

The number of meshes and the number of RF paths in this disclosure may be 3 but the number can vary according to system's conditions and requirements.

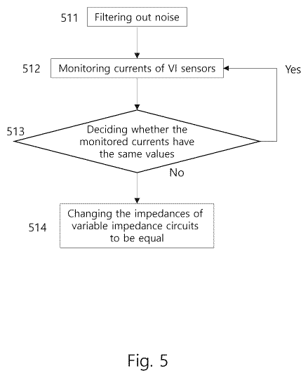

FIG. 5 illustrates a method of plasma modulation according to another embodiment of the present disclosure.

The controller 425 may monitor constantly on each of the RF rods 401, 402, 403. That means the controller 425 may monitor the currents (i1, i2, i3) of the VI sensors (451, 452, 453) respectively (512). Given the monitored current values, the controller 425 may compare the current values and may decide if the monitored currents are the same is true. (513).

If the decision may be false, the controller 425 may change the impedances of the variable impedance circuits to be equal among themselves and if to be true, the controller 425 keeps monitoring the currents of VI sensors (514).

Before monitoring, the RF filter 450 would be used to filter out noise from respective RF rods for better signal measurement in the VI sensors. (511)

The above-described arrangement of apparatus is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A plasma modulation apparatus for use in a substrate processing system, the apparatus comprising:
a plurality of radio frequency (RF) paths connected to N different meshes, wherein a susceptor of the substrate processing system is divided into the N different meshes and N is an integer equal to or greater than 2,
wherein each of the RF paths comprises:
an RF rod connected to one of the N different meshes and configured to transmit RF signal from the connected mesh;
a Voltage-Current (VI) sensor connected to the RF rod and configured to measure a current from the RF rod; and
a variable impedance circuit connected to the VI sensor and configured to change an impedance of the RF path and further configured to be grounded,
wherein each of the RF paths are grounded separately and each of the RF paths corresponds to a different mesh, respectively.

2. The apparatus according to claim 1, further comprising:
an RF filter configured to filter out noise from the RF rod.

3. The plasma modulation apparatus according to claim 1, further comprising:
a controller coupled to each of the RF paths and configured to monitor the currents of each of the VI sensors and to change impedances of each of the RF paths based on the monitored currents.

4. The plasma modulation apparatus according to claim 3, wherein the controller is configured to change the impedances of the plurality of RF paths to be equal among themselves.

5. A substrate processing system comprising:
a reaction chamber disposed with a showerhead and a susceptor for supporting a wafer, the susceptor divided into N different meshes, wherein N is an integer equal to or greater than 2; and
a plasma modulation apparatus comprising:
a plurality of radio frequency (RF) paths connected to the N different meshes,
wherein each of the RF paths comprises:
an RF rod connected to one of the N different meshes and configured to transmit RF signal from the connected mesh;
a Voltage-Current (VI) sensor connected to the RF rod and configured to measure a current from the RF rod; and
a variable impedance circuit connected to the VI sensor and configured to change an impedance of the RF path and further configured to be grounded, and
wherein each of the RF paths are grounded separately and each of the RF paths corresponds to a different mesh, respectively.

6. The substrate processing system according to claim 5, further comprising:
an RF filter configured to filter out noises from the RF rod.

7. The substrate processing system according to claim 5, further comprising:
a controller connected to each of the RF paths and configured to monitor the currents of each of the VI sensors and to change impedances of each of the RF paths based on the monitored currents.

8. The substrate processing system according to claim 7, wherein the controller is configured to change the impedances of the plurality of RF paths to be equal among themselves.

9. A method of modulating plasma in a substrate processing system, the system comprises a reaction chamber disposed with a susceptor, the susceptor being divided into N different meshes, wherein N is an integer equal to or greater than 2, and a plasma modulation apparatus comprising a plurality of radio frequency (RF) paths connected to the N different meshes, and each of the RF paths disposed an RF rod, a Voltage-Current (VI) sensor and a variable impedance circuit, the method comprising:
monitoring the currents of all the VI sensors from respective RF paths;
deciding whether the monitored currents have the same value is true; and
changing the impedances of variable impedance circuits from respective RF paths to be equal if decided to be false and repeat deciding if decided to be true.

10. The method of modulating plasma according to the claim 9, further comprising:
filtering our noise from each of the RF rods.
